(19) United States
(12) Patent Application Publication
(10) Pub. No.: US 2018/0203350 A1
(43) Pub. Date: Jul. 19, 2018

(54) PHOTOSENSITIVE RESIN COMPOSITION, METHOD FOR MAKING PHOTOSENSITIVE RESIN COMPOSITION, AND METHOD FOR MAKING PRINTED CIRCUIT BOARD THEREWITH

(71) Applicant: Zhen Ding Technology Co., Ltd., Tayuan (TW)

(72) Inventors: MAO-FENG HSU, New Taipei (TW); CHEN-FENG YEN, New Taipei (TW); SHOU-JUI HSIANG, New Taipei (TW); YEN-CHIN HSIAO, New Taipei (TW)

(21) Appl. No.: 15/482,946

(22) Filed: Apr. 10, 2017

(30) Foreign Application Priority Data
Jan. 14, 2017 (TW) 106101318

(51) Int. Cl. G03F 7/031; G03F 7/004; G03F 7/039; G03F 7/038; G03F 7/16; G03F 7/20; G03F 7/32; G03F 7/40; H05K 3/00

(52) U.S. Cl. CPC G03F 7/031; G03F 7/0048; G03F 7/039; G03F 7/038; H05K 3/0023; G03F 7/168; G03F 7/2004; G03F 7/32; G03F 7/40; G03F 7/16

(57) ABSTRACT

A photosensitive resin composition which is non-reactive and thus storable at a normal temperatures includes 100 parts (by weight) of an epoxy acrylate, 10-50 parts acrylate monomers, 1-40 parts acrylate oligomers, 5-15 parts of a photoinitiator, 1-5 parts of a coloring agent, and 10-50 parts of a blocked polyisocyanate. A method of making and a printed circuit board made accordingly are also disclosed.

### FIELD

The subject matter herein generally relates to a resin composition, and more particularly, to a photosensitive resin composition, a method for making the photosensitive resin composition, and a method for making a printed circuit board.

### BACKGROUND

Printed circuit boards (PCBs) usually include green solder mask coatings applied to the copper traces for protection against oxidation, and to prevent solder bridges being generated between adjacent solder pads. The green solder mask coating is formed by a green solder mask ink, which includes a base agent and a hardening agent. The base agent comprises epoxy acrylate. The hardening agent comprises epoxy resin. The epoxy acrylate usually includes carboxyl groups (—COOH) so that the green solder mask coating can be etched by an alkali solution during exposure and development. However, the epoxy groups of the epoxy resin may react with the carboxyl groups of the epoxy acrylate at normal temperature, so that the green solder mask ink must be stored at a temperature lower than 5 degrees Celsius, which increases the cost for storage.

### BRIEF DESCRIPTION OF THE DRAWINGS

Implementations of the present technology will now be described, by way of example only, with reference to the attached figures.

FIG. 1 is a flowchart of an exemplary embodiment of a method for making a photosensitive resin composition.

FIG. 2 is a flowchart of an exemplary embodiment of a method for making a printed circuit board.

FIG. 3 is a diagrammatic view of an exemplary embodiment showing photosensitive resin composition being coated on a release film.

FIG. 4 is a diagrammatic view showing the photosensitive resin composition of FIG. 3 being pre-cured to form a photosensitive resin composition layer.

FIG. 5 is a diagrammatic view showing a copper foil being formed on the photosensitive resin composition layer of FIG. 4.

FIG. 6 is a diagrammatic view showing the photosensitive resin composition layer of FIG. 5 being performed by an exposure and development process and the releasing film being removed.

FIG. 7 is a diagrammatic view showing the photosensitive resin composition layer of FIG. 6 being cured to form a printed circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

An exemplary embodiment of a photosensitive resin composition comprises an epoxy acrylate, acrylate monomers, acrylate oligomers, a photoinitiator, a coloring agent, and a blocked polyisocyanate. The photosensitive resin composition comprises no epoxy resin. The epoxy acrylate is in an amount by weight of about 100 parts in the photosensitive resin composition. The acrylate monomers are in an amount by weight of about 10 parts to about 50 parts in the photosensitive resin composition. The acrylate oligomers are in an amount by weight of about 10 parts to about 40 parts in the photosensitive resin composition. The photoinitiator is in an amount by weight of about 5 parts to about 15 parts in the photosensitive resin composition. The coloring agent is in an amount by weight of about 1 part to about 5 parts in the photosensitive resin composition. The blocked polyisocyanate is in an amount by weight of about 10 parts to about 50 parts in the photosensitive resin composition. The photosensitive resin composition can be used to make paint, a dry film, or a photosensitive solder mask of a printed circuit board.

In at least one exemplary embodiment, the photosensitive resin composition can further comprise a solvent for adjusting a viscosity of the photosensitive resin composition. The solvent can be butanone.

The epoxy acrylate comprises reactive functional groups selected from benzene ring, carboxyl group (—COOH), and hydroxy group (—OH). The number of the reactive functional groups is selected between two and four. In at least one exemplary embodiment, the epoxy acrylate has a molecular weight of about 10000 g/mol to about 40000 g/mol. The epoxy acrylate has an acid value of about 70 mgKOH/g to about 150 mgKOH/g.

Each of the acrylate monomer and the acrylate oligomer has a plurality of reactive functional groups, so that the acrylate monomer, the acrylate oligomer, and the epoxy acrylate can be polymerized when the photosensitive resin composition is exposed to ultraviolet radiation.

In at least one exemplary embodiment, the number of the reactive functional groups of the acrylate monomer is greater than or equal to three. The acrylate monomer can be selected from a group consisting of polyethyleneglycol diacrylate (PEGDA), 1,6-Hexanediol diacrylate (HDDA), ethoxylated bisphenol A diacrylate (BPA), trimethylolpropane triacrylate (TMPTA), pentaerythritol triacrylate (PETA), dipentaerythritol hexaacrylate (DPHA), ethoxylated trimethylolpropane triacrylate [TMP(EO)TA], and propoxylated (3) trimethylolpropane triacrylate [TMP(3PO)TA], or any combination thereof.

The acrylate oligomer can be aliphatic urethane acrylate. The number of the reactive functional groups of the acrylate oligomer is selected between two and four. The acrylate oligomer has a molecular weight of about 3000 g/mol to about 6000 g/mol.

The photoinitiator can absorb ultraviolet radiation to generate free radicals or positive ions when the photosensitive resin composition is exposed to ultraviolet radiation. The free radicals or positive ions can cause the epoxy acrylate, the acrylate monomers, and the acrylate oligomers to polymerize. The photoinitiator may be selected from a group consisting of α-hydroxy ketones, acylphosphine oxide, amino ketone compound, and oxime ester compound, or any combination thereof. In at least one exemplary embodiment, the photoinitiator can be selected from a group consisting of 2-hydroxy-2-methyl-1-phenyl-1-acetone, 1-hydroxy cyclohexyl phenyl ketone, Diphenyl(2,4,6-trimethylbenzoyl)phosphine oxide, 2-methyl-4′-(methylthio)-2-morpholinopropiophenone, phenyl bis(2,4,6-trimethylbenzoyl)-phosphine oxide, 2-Benzyl-2-(dimethylamino)-4′-morpholinobutyrophenone, 2,2-dimethoxy-2-phenylacetophenone, benzophenone, isopropyl thioxanthone, and carbazole oxime ester, or any combination thereof.

The blocked polyisocyanate are formed by blocking reactive isocyanate groups (—NCO) of polyisocyanate (graphic chemical formula is:

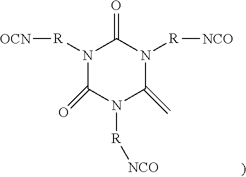

through a blocking agent (BL). The blocking agent may deblock the isocyanate groups when the blocked polyisocyanate is heated to a deblocking temperature higher than the normal temperature. That is, the isocyanate groups can react with the carboxyl group or the hydroxy group of the epoxy acrylate only when the blocked polyisocyanate is heated to the deblocking temperature. On the other hand, the isocyanate groups are not reactive when the blocked polyisocyanate is heated to less than the deblocking temperature (for example, the blocked polyisocyanate is heated at normal temperature). Moreover, the photosensitive resin composition comprises no epoxy resin. Thus, the photosensitive resin composition has an improved storage stability at normal temperature.

In at least one exemplary embodiment, the polyisocyanate can be aromatic polyisocyanate or aliphatic polyisocyanate. The aromatic polyisocyanate can be polymerized by 2,4-toluene diisocyanate (TDI) or 4,4′-diphenyl-methane diisocyanate (MDI) to form TDI polyisocyanate or MDI polyisocyanate. The aliphatic polyisocyanate (graphic chemical formula is:

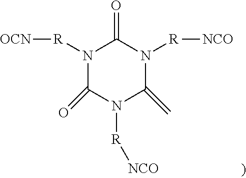

can be polymerized by hexamethylene diisocyanate (HDI, wherein R is —(CH₂)₆—) or isophorone diisocyanate (IPDI, wherein R is

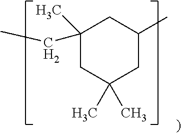

to form HDI polyisocyanate or IPDI polyisocyanate. That is, the isocyanate groups of the TDI polyisocyanate, the MDI polyisocyanate, the HDI polyisocyanate, or the IPDI polyisocyanate are blocked to form blocked TDI polyisocyanate, blocked MDI polyisocyanate, blocked HDI polyisocyanate, or blocked IPDI polyisocyanate. The blocking and deblocking of the isocyanate groups are illustrated as follows:

R—N═C═O+BL-⇔R—NH—(═O)—BL

In at least one exemplary embodiment, the polyisocyanate is aliphatic polyisocyanate which has a long aliphatic chain, so as to improve the flexibility of the photosensitive resin composition.

The blocking agent can be selected from a group consisting of ε-caprolactam (ε-CAP), methylethylketoxime (MEKO), 3,5-dimethylpyrazole (DMP), and diethylmalonate (DEM), or any combination thereof. Different blocking agents may cause different deblocking temperatures for the isocyanate groups. When the blocking agent is ε-caprolactam, the isocyanate groups have a deblocking temperature of 160-180 degrees Celsius. When the blocking agent is methylethylketoxime, the isocyanate groups have a deblocking temperature of 140 degrees Celsius to 160 degrees Celsius. When the blocking agent is 3,5-dimethylpyrazole, the isocyanate groups have a deblocking temperature of 110 degrees Celsius to 120 degrees Celsius. When the blocking agent is diethylmalonate, the isocyanate groups have a deblocking temperature of 100 degrees Celsius to 120 degrees Celsius.

The coloring agent can allow desired colors for the photosensitive resin composition. The coloring agent can be selected from a group consisting of a pigment, a dye, or any combination thereof. The pigment can be selected from a group consisting of an inorganic pigment, an organic pigment, or any combination thereof. In at least one exemplary embodiment, the pigment can be selected from a group consisting of phthalo blue, phthalo green, crystal violet, titanium dioxide, carbon black, iron oxide black, aniline black, or any combination thereof. The dye can be selected from a group consisting of natural organic dye, synthesized organic dye, or any combination thereof. In at least one exemplary embodiment, the dye can be selected from a group consisting of Kayase Red-B (trade name, available commercially from NIPPON KAYAKU), Black-AN (trade name, available commercially from NIPPON KAYAKU), Neozapon Red 355 (trade name, available commercially from BASF Corporation), Orasol Black-X55 (trade name, available commercially from BASF Corporation), Oracet Yellow-144FE (trade name, available commercially from BASF Corporation), or any combination thereof.

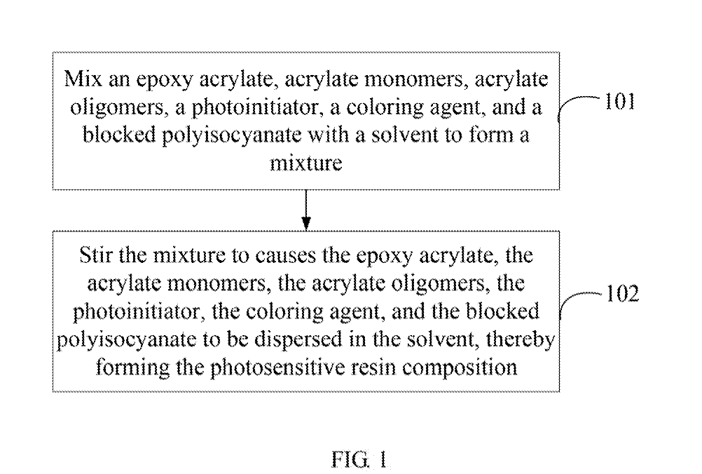

FIG. 1 illustrates a flowchart of a method for making the photosensitive resin composition in accordance with an exemplary embodiment. The exemplary method is provided by way of example, as there are a variety of ways to carry out the method. Each block shown in the figure represents one or more processes, methods or subroutines, carried out in the exemplary method. Furthermore, the illustrated order of blocks is by example only, and the order of the blocks can change. Additional blocks may be added, or fewer blocks may be utilized, without departing from this disclosure. The exemplary method can begin at block 101.

At block 101, an epoxy acrylate, acrylate monomers, acrylate oligomers, a photoinitiator, a coloring agent, and a blocked polyisocyanate are mixed with a solvent to form a mixture. The epoxy acrylate is in an amount by weight of about 100 parts in the mixture. The acrylate monomers are in an amount by weight of about 10 parts to about 50 parts in the mixture. The acrylate oligomers are in an amount by weight of about 10 parts to about 40 parts in the mixture. The photoinitiator is in an amount by weight of about 5 parts to about 15 parts in the mixture. The coloring agent is in an amount by weight of about 1 part to about 5 parts in the mixture. The blocked polyisocyanate is in an amount by weight of about 10 parts to about 50 parts in the mixture.

At blocked 102, the mixture is stirred to causes the epoxy acrylate, the acrylate monomers, the acrylate oligomers, the photoinitiator, the coloring agent, and the blocked polyisocyanate to be dispersed in the solvent, thereby forming the photosensitive resin composition.

In at least one exemplary embodiment, the solvent can be butanone. The amount of the solvent can be adjusted, ensuring that all the above components can be dissolved in the solvent.

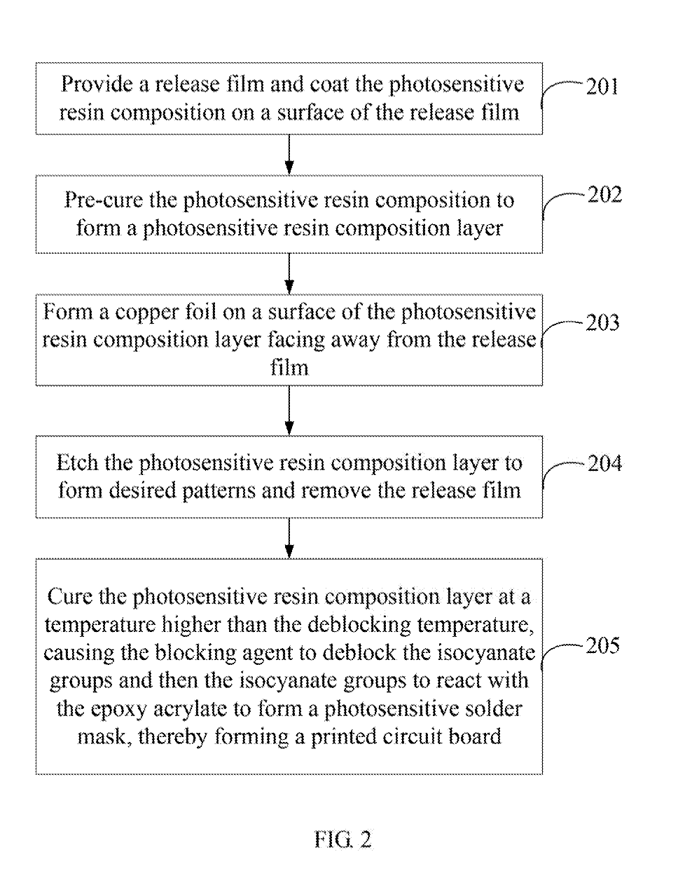

FIG. 2 illustrates a flowchart of a method for making a printed circuit board 100 in accordance with an exemplary embodiment. The exemplary method is provided by way of example, as there are a variety of ways to carry out the method. Each block shown in the figure represents one or more processes, methods or subroutines, carried out in the exemplary method. Furthermore, the illustrated order of blocks is by example only, and the order of the blocks can change. Additional blocks may be added, or fewer blocks may be utilized, without departing from this disclosure. The exemplary method can begin at block 201.

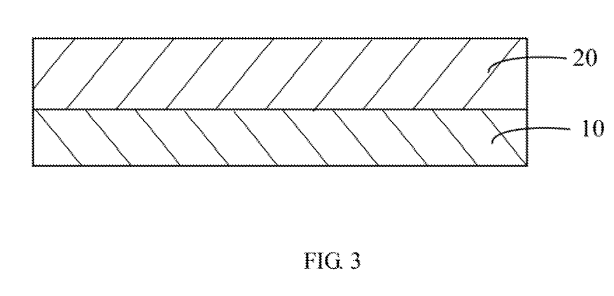

At block 201, referring to FIG. 3, a release film 10 is provided, and the photosensitive resin composition 20 is coated on a surface of the release film 10.

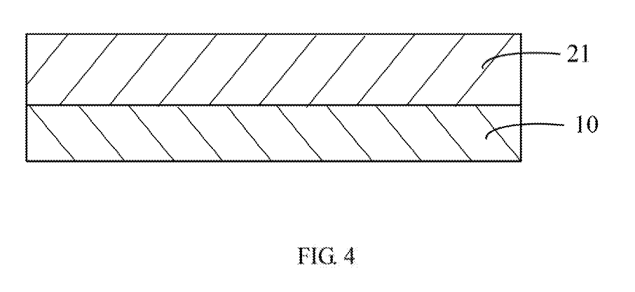

At block 202, referring to FIG. 4, the photosensitive resin composition is pre-cured and semi-solidified, thereby forming a photosensitive resin composition layer 21. In at least one exemplary embodiment, the photosensitive resin composition is pre-cured at 80 degrees Celsius for about 20 min.

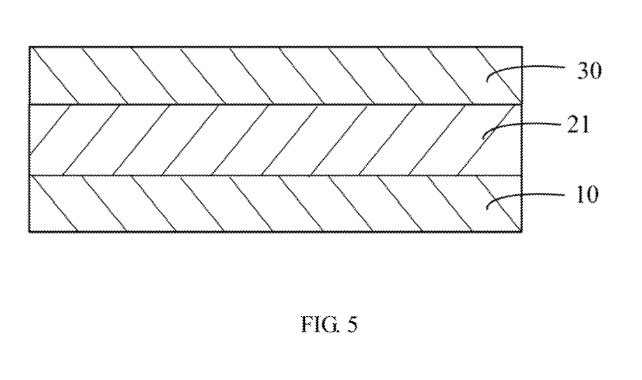

At block 203, referring to FIG. 5, a copper foil 30 is formed on a surface of the photosensitive resin composition layer 21 facing away from the release film 10.

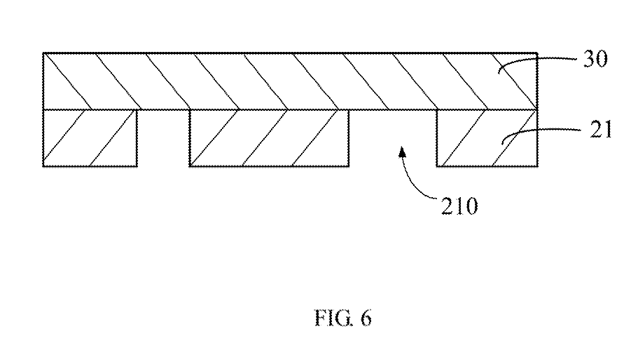

At block 204, referring to FIG. 6, the photosensitive resin composition layer 21 is etched by exposure and development to form desired patterns 210, and the release film 10 is removed to expose the copper foil 30.

In at least one exemplary embodiment, the exposure can be carried out by placing the photosensitive resin composition layer 21 in an ultraviolet exposure device (not shown); covering a dry film 40 on a surface of the release film 10 facing away from the photosensitive resin composition layer 21, so that the dry film 40 can face an ultraviolet source of the ultraviolet exposure device; controlling the ultraviolet source to emit ultraviolet light towards the photosensitive resin composition layer 21, thereby causing the epoxy acrylate to react with the acrylate monomers and the acrylate oligomers through the unsaturated double bond (—HC═CH₂). That is, the epoxy acrylate, the acrylate monomers, and the acrylate oligomers undergo an ultraviolet solidifying reaction. In at least one exemplary embodiment, a power of the ultraviolet exposure is about 400 mj/cm².

In at least one exemplary embodiment, the development can be carried out by: removing the dry film 40 and the release film 10; etching a portion of the photosensitive resin composition layer 21 which is not exposed. In at least one exemplary embodiment, the photosensitive resin composition layer 21 is etched by a sodium hydroxide solution having a mass concentration of about 1%.

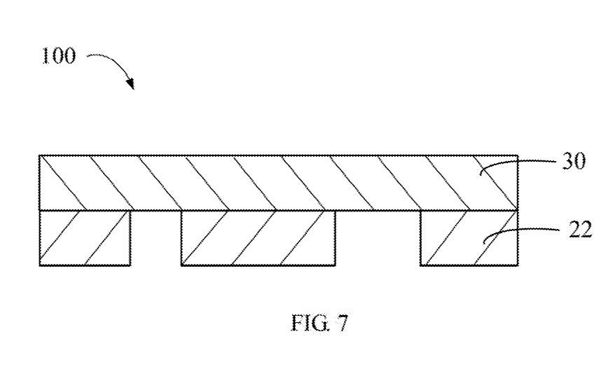

At block 205, referring to FIG. 7, the photosensitive resin composition layer 21 after the exposure and development is cured at a temperature higher than the deblocking temperature, causing the blocking agent to deblock the isocyanate groups and then the isocyanate groups to react with the carboxyl group or the hydroxy group of the epoxy acrylate to form a photosensitive solder mask 22, thereby forming the printed circuit board 100. That is, the isocyanate groups and the carboxyl group or the hydroxy group of the epoxy acrylate undergo a thermal solidifying reaction. In at least one exemplary embodiment, the photosensitive resin composition layer 21 is cured at 150 degrees Celsius for about 1.5 hours. In detail, the isocyanate groups react with the carboxyl group to form amide (graphic chemical formula is:

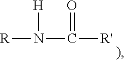

and react with the hydroxy group to form ethyl carbamate (graphic chemical formula is:

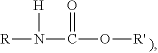

which can be shown as follows:

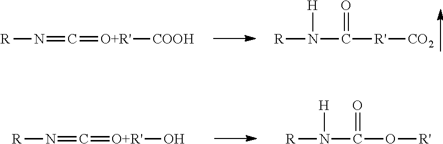

The thermal solidification reaction can form a cross-linking network structure which can improve a cross-linking density of the photosensitive resin composition so that the photosensitive solder mask 22 can have an improved alkalis resistance and solder heat resistance, and the printed circuit board 100 can have an improved thermal resistance.

### Example 1

Epoxy acrylate (molecular weight of 10000 g/mol, acid value of 100 mgKOH/g) in an amount by weight of 100 parts, TMP(3PO)TA in an amount by weight of 40 parts, aliphatic urethane acrylate in an amount by weight of 15 parts, photoinitiator in an amount by weight of 8 parts, coloring agent in an amount by weight of 2 parts, butanone in an amount by weight of 30 parts, and blocked HDI polyisocyanate in an amount by weight of 20 parts were added into a container of 500 mL to form a mixture, the mixture were stirred to form the photosensitive resin composition.

### Example 2

Epoxy acrylate (molecular weight of 10000 g/mol, acid value of 100 mgKOH/g) in an amount by weight of 100 parts, TMP(3PO)TA in an amount by weight of 20 parts, aliphatic urethane acrylate in an amount by weight of 30 parts, photoinitiator in an amount by weight of 8 parts, coloring agent in an amount by weight of 2 parts, butanone in an amount by weight of 30 parts, and blocked HDI polyisocyanate in an amount by weight of 40 parts were added into a container of 500 mL to form a mixture, the mixture were stirred to form the photosensitive resin composition.

### Example 3

Epoxy acrylate (molecular weight of 10000 g/mol, acid value of 100 mgKOH/g) in an amount by weight of 100 parts, TMP(3PO)TA in an amount by weight of 20 parts, aliphatic urethane acrylate in an amount by weight of 30 parts, photoinitiator in an amount by weight of 8 parts, coloring agent in an amount by weight of 2 parts, butanone in an amount by weight of 30 parts, and blocked IPDI polyisocyanate in an amount by weight of 40 parts were added into a container of 500 mL to form a mixture, the mixture were stirred to form the photosensitive resin composition.

### Comparative Example 1

Epoxy acrylate (molecular weight of 10000 g/mol, acid value of 100 mgKOH/g) in an amount by weight of 100 parts, TMP(3PO)TA in an amount by weight of 20 parts, aliphatic urethane acrylate in an amount by weight of 30 parts, photoinitiator in an amount by weight of 8 parts, coloring agent in an amount by weight of 2 parts, and butanone in an amount by weight of 30 parts were added into a container of 500 mL to form a mixture, the mixture were stirred to form a resin composition.

### Comparative Example 2

Epoxy acrylate (molecular weight of 10000 g/mol, acid value of 100 mgKOH/g) in an amount by weight of 100 parts, TMP(3PO)TA in an amount by weight of 20 parts, aliphatic urethane acrylate in an amount by weight of 30 parts, photoinitiator in an amount by weight of 8 parts, coloring agent in an amount by weight of 2 parts, butanone in an amount by weight of 30 parts, and bisphenol A epoxy resin (epoxy equivalent of 188 g/eq) in an amount by weight of 18.5 parts were added into a container of 500 mL to form a mixture, the mixture were stirred to form a resin composition.

Printed circuit boards were formed by the photosensitive resin compositions of the above examples 1-3 and the resin compositions of the above comparative examples 1-2. The printed circuit boards were performed by a copper chloride test, an adhesion strength test under ASTM standard, an alkalis resistance test, a thermal resistance test, a flexibility test, and a storage stability test at normal temperature. The test results are shown in table 1. The copper chloride test was carried out by immersing the printed circuit boards into a copper chloride solution and observing whether discolor happened to the copper foil, thereby determining whether the desired portion of the photosensitive resin composition layers were completely etched during the development. The alkalis resistant test was carried out by immersing the printed circuit boards into a sodium hydroxide solution having a mass concentration of about 10% and observing whether the photosensitive solder masks were peeled off. The flexibility test was carried out by bending the printed circuit boards through 180 degrees and calculating the number of times that the printed circuit board remained non-fractured after being bent. The thermal resistance test was carried out by exposing the printed circuit board to a temperature equal to or greater than 260 degrees Celsius for 30 seconds and observing whether the photosensitive solder masks were peeled off or dropped out from the printed circuit boards. The storage stability test at normal temperature was carried out by making the printed circuit boards by the photosensitive resin compositions and the resin compositions which are stored at the normal temperature for one month, repeating the copper chloride test, the adhesion strength test, the alkalis resistance test, and the thermal resistance test, and determining whether the test results were deteriorated. If so, the properties of the photosensitive resin compositions or the resin compositions remain unchanged during the storage; otherwise, the properties were changed during the storage.

TABLE 1

| | Product | | | | |
|---|---|---|---|---|---|
| | | | | comparative | comparative |
| property | example 1 | Example 2 | example 3 | example 1 | example 2 |
| copper | immediately | immediately | no discolor | immediately | discolor after |
| chloride test | discolor | discolor | after 10 | discolor | 10 seconds |
| | | | seconds | | |
| adhesion | 5B | 5B | 4B | 4B | 4B |
| strength | | | | | |
| alkalis | not peeled | not peeled off | not peeled | peeled off after | generate |
| resistance | off after 30 min | after 30 min | off after 30 min | 30 min | minor holes |
| | | | | | after 30 min |
| thermal | 300 degrees | 300 degrees | 300 degrees | 260 degrees | 288 degrees |
| resistance | Celsius 30 s | Celsius 30 s | Celsius 30 s | Celsius 30 s | Celsius 30 s |
| flexibility | 3 | 10 | 7 | 1 | 1 |
| storage | unchanged | unchanged | unchanged | unchanged | changed |
| stability | | | | | |

Table 1 illustrates that the photosensitive resin compositions of the above examples 1-3 have improved storage stability, comparing to the resin composition of the above comparative example 2 formed by the (bisphenol A) epoxy resin. The printed circuit boards formed by the photosensitive resin compositions of the above examples 1-3 have improved alkalis resistance, thermal resistance, and flexibility, comparing to the printed circuit boards formed by the resin composition of the above comparative examples 1-2. The printed circuit board formed by photosensitive resin composition of the above example 2 comprising the blocked HDI polyisocyanate has improved developing property, adhesion strength, and flexibility.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

1. A photosensitive resin composition comprising:
a derivative of epoxy acrylate in an amount by weight of about 100 parts in the photosensitive resin composition;
acrylate monomers in an amount by weight of about 10 parts to about 50 parts in the photosensitive resin composition;
acrylate oligomers in an amount by weight of about 10 parts to about 40 parts in the photosensitive resin composition;
a photoinitiator in an amount by weight of about 5 parts to about 15 parts in the photosensitive resin composition;
a coloring agent in an amount by weight of about 1 part to about 5 parts in the photosensitive resin composition; and
a blocked polyisocyanate in an amount by weight of about 10 parts to about 50 parts in the photosensitive resin composition;
wherein the photosensitive resin composition comprises no epoxy resin;
wherein the blocked polyisocyanate is formed by blocking reactive isocyanate groups of a polyisocyanate through a blocking agent, the blocking agent deblock the isocyanate groups when the blocked polyisocyanate is heated to a deblocking temperature higher than a room temperature.

2. The photosensitive resin composition of claim 1, further comprising a solvent.

3. The photosensitive resin composition of claim 2, wherein the solvent is butanone.

4. The photosensitive resin composition of claim 1, wherein the derivative of epoxy acrylate comprises reactive functional groups selected from benzene ring, carboxyl group, and hydroxy group, a number of the reactive functional groups is selected between two and four.

5. The photosensitive resin composition of claim 4, wherein the derivative of epoxy acrylate has a molecular weight of 10000 g/mol to 40000 g/mol, the derivative of epoxy acrylate has an acid value of 70 mgKOH/g to 150 mgKOH/g.

6. The photosensitive resin composition of claim 1, wherein each of the acrylate monomers has a plurality of acrylate functional groups, a number of the acrylate functional groups of each of the acrylate monomers is greater than or equal to two.

7. The photosensitive resin composition of claim 6, wherein each of the acrylate monomers is selected from a group consisting of polyethyleneglycol diacrylate, 1,6-Hexanediol diacrylate, ethoxylated bisphenol A diacrylate, trimethylolpropane triacrylate, pentaerythritol triacrylate, dipentaerythritol hexaacrylate, ethoxylated trimethylolpropane triacrylate, propoxylated (3) trimethylolpropane triacrylate, and any combination thereof.

8. The photosensitive resin composition of claim 1, wherein each of the acrylate oligomers has a plurality of acrylate functional groups, a number of the reactive functional groups of each of the acrylate oligomers is selected between two and four.

9. The photosensitive resin composition of claim 8, wherein each of the acrylate oligomers is aliphatic urethane acrylate.

10. The photosensitive resin composition of claim 8, wherein each of the acrylate oligomers has a molecular weight of 3000 g/mol to 6000 g/mol.

11. The photosensitive resin composition of claim 1, wherein the photoinitiator is selected from a group consisting of α-hydroxy ketones, acylphosphine oxide, amino ketone compound, oxime ester compound, and any combination thereof.

12. The photosensitive resin composition of claim 10, wherein the photoinitiator is selected from a group consisting of 2-hydroxy-2-methyl-1-phenyl-1-acetone, 1-hydroxy cyclohexyl phenyl ketone, Diphenyl(2,4,6-trimethylbenzoyl)phosphine oxide, 2-methyl-4′-(methylthio)-2-morpholinopropiophenone, phenyl bis(2,4,6-trimethylbenzoyl)-phosphine oxide, 2-Benzyl-2-(dimethylamino)-4′-morpholinobutyrophenone, 2,2-dimethoxy-2-phenylacetophenone, benzophenone, isopropyl thioxanthone, carbazole oxime ester, and any combination thereof.

13. The photosensitive resin composition of claim 1, wherein the polyisocyanate is an aromatic polyisocyanate obtained by polymerizing 2,4-toluene diisocyanate or 4,4′-diphenyl-methane diisocyanate.

14. The photosensitive resin composition of claim 1, wherein the polyisocyanate is an aliphatic polyisocyanate obtained by polymerizing hexamethylene diisocyanate or isophorone diisocyanate.

15. The photosensitive resin composition of claim 1, wherein the blocking agent is selected from a group consisting of ε-caprolactam, methylethylketoxime, 3,5-dimethylpyrazole, diethylmalonate, and any combination thereof.

16. The photosensitive resin composition of claim 1, wherein the coloring agent is selected from a group consisting of a pigment, a dye, and any combination thereof.

17. A method for making a photosensitive resin composition comprising:
mixing a derivative of epoxy acrylate, acrylate monomers, acrylate oligomers, a photoinitiator, a coloring agent, and a blocked polyisocyanate with a solvent to form a mixture, the derivative of epoxy acrylate being in an amount by weight of about 100 parts in the mixture, the acrylate monomers being in an amount by weight of about 10 parts to about 50 parts in the mixture, the acrylate oligomers being in an amount by weight of about 10 parts to about 40 parts in the mixture, the photoinitiator being in an amount by weight of about 5 parts to about 15 parts in the mixture, the coloring agent being in an amount by weight of about 1 part to about 5 parts in the mixture, the blocked polyisocyanate being in an amount by weight of about 10 parts to about 50 parts in the mixture; and
stirring the mixture to cause the derivative of epoxy acrylate, the acrylate monomers, the acrylate oligomers, the photoinitiator, the coloring agent, and the blocked polyisocyanate to be dispersed in the solvent, thereby forming the photosensitive resin composition;
wherein the photosensitive resin composition comprises no epoxy resin;
wherein the blocked polyisocyanate is formed by blocking reactive isocyanate groups of a polyisocyanate through a blocking agent, the blocking agent deblock the isocyanate groups when the blocked polyisocyanate is heated to a deblocking temperature higher than a normal room temperature.

18. A method for making a printed circuit board comprising:
providing a release film;
coating a photosensitive resin composition on a surface of the release film, the photosensitive resin composition comprising a derivative of epoxy acrylate in an amount by weight of about 100 parts in the photosensitive resin composition, acrylate monomers in an amount by weight of about 10 parts to about 50 parts in the photosensitive resin composition, acrylate oligomers in an amount by weight of about 10 parts to about 40 parts in the photosensitive resin composition, a photoinitiator in an amount by weight of about 5 parts to about 15 parts in the photosensitive resin composition, a coloring agent in an amount by weight of about 1 part to about 5 parts in the photosensitive resin composition, and a blocked polyisocyanate in an amount by weight of about 10 parts to about 50 parts in the photosensitive resin composition, wherein the photosensitive resin composition comprises no epoxy resin, the blocked polyisocyanate is formed by blocking reactive isocyanate groups of a polyisocyanate through a blocking agent, the blocking agent deblock the isocyanate groups when the blocked polyisocyanate is heated to a deblocking temperature higher than a room temperature;
pre-curing the photosensitive resin composition to form a photosensitive resin composition layer;
forming a copper foil on a surface of the photosensitive resin composition layer facing away from the release film;
etching the photosensitive resin composition layer by exposure and development to form desired patterns, and removing the release film to expose the copper foil, wherein the exposure is carried out by exposing a portion of the photosensitive resin composition layer to ultraviolet light to cause the portion of the photosensitive resin composition layer to be polymerized, the development is carried out by etching a remaining portion of the photosensitive resin composition layer which is not polymerized; and
curing the photosensitive resin composition layer after the exposure and development at a temperature higher than the deblocking temperature, causing the blocking agent to deblock the isocyanate groups and then the isocyanate groups to react with the derivative of epoxy acrylate to form a solder mask, thereby forming the printed circuit board.

19. The method of claim 18, wherein the photosensitive resin composition is pre-cured at 80 degrees Celsius for about 20 min.
